(19) United States
(12) Patent Application Publication
(10) Pub. No.: US 2025/0280721 A1
(43) Pub. Date: Sep. 4, 2025

(54) DISPLAY DEVICE

(71) Applicant: LG Display Co., Ltd., Seoul (KR)

(72) Inventors: Dongmin LIM, Paju-si (KR); KyungYun KANG, Paju-si (KR)

(73) Assignee: LG Display Co., Ltd., Seoul (KR)

(21) Appl. No.: 18/761,654

(22) Filed: Jul. 2, 2024

(30) Foreign Application Priority Data
Feb. 29, 2024 (KR) 10-2024-0030246

(51) Int. Cl. H10K 59/88; H10K 59/12; H10K 59/124; H10K 59/126; H10K 59/131

(52) U.S. Cl. CPC H10K 59/88; H10K 59/1201; H10K 59/124; H10K 59/126; H10K 59/131

(57) ABSTRACT

A display device may include a thin film transistor having a gate electrode, a gate insulating layer and a drain electrode. A first conductive layer of the gate electrode may include a material having a lower reflectivity than a second conductive layer of the gate electrode, a dummy conductive layer may be disposed between the gate insulating layer and the drain electrode, the dummy conductive layer may be spaced apart from a semiconductor layer, and the drain electrode may be in direct contact with the semiconductor layer. A method of manufacturing a display device is also disclosed.

### CROSS-REFERENCE TO RELATED APPLICATIONS

This application claims the benefit of and priority to Korean Patent Application No. 10-2024-0030246 filed on Feb. 29, 2024, the entirety of which is incorporated herein by reference for all purposes as if fully set forth herein.

### BACKGROUND

### 1. Technical Field

The present disclosure relates to an apparatus and a method, and particularly to, for example, without limitation, a display device and a method of manufacturing a display device.

### 2. Description of the Related Art

The display device is widely used as a display screen of a notebook computer, a tablet computer, a smart phone, a portable display device, and a portable information device in addition to a display screen of a television or a monitor. With the advancement of technology, a display device may provide photographing or various sensing functions in addition to an image display function. Accordingly, the display device may include an electronic device such as a camera or a sensor.

Among the display devices, an organic light emitting display device is a self-emission type, and offers advantages such as a superior viewing angle and contrast ratio compared to a liquid crystal display (LCD). Further, an organic light emitting display device can achieve light weight and thinness because no separate backlight is required, and it can also offer the advantage of lower power consumption. In addition, an organic light emitting display device has the advantage of being able to operate with low DC voltage, provide fast response speed, and especially maintain low manufacturing costs.

An organic light emitting display device may display an image by driving a light emitting device through various elements. For example, the organic light emitting display device may include an electronic device such as a driving thin film transistor, a switching transistor, and a capacitor. Since such electronic devices include an electrode formed of a metal material, electronic devices may reflect light that penetrates from the outside. Accordingly, a reflectivity with respect to external light may increase and visibility may decrease.

To solve this problem, according to one approach, an electrode is formed using a conductive material having a low reflectivity. In this case, in order to prevent an increase in resistance of a contact region, the electrode formed in the contact region may be removed. In this case, when the conductive material having the low reflectivity is etched compared to the conductive material having a high reflectivity, the electrode may not be stably etched. Accordingly, a residual film may be generated and the display device may not be normally driven.

The description of the related art should not be assumed to be prior art merely because it is mentioned in or associated with this section. The description of the related art includes information that describes one or more aspects of the subject technology, and the description in this section does not limit the invention.

### SUMMARY

The inventors of the present disclosure have recognized the problems and needs of the related art, have performed extensive research and experiments, and have developed a new invention. In one or more aspects, an object of the present disclosure is to provide a display device with a reduced possibility of residual film generation.

In accordance with one or more aspects of the present disclosure, the above and other objects can be accomplished by the provision of a display device that may comprise a substrate, a display area including a plurality of sub-pixels divided by a plurality of signal lines, and a non-display area surrounding the display area, wherein each of the plurality of sub-pixels includes a thin film transistor disposed on a substrate, the thin film transistor includes a semiconductor layer disposed on the substrate, a gate insulating layer disposed on the semiconductor layer, a gate electrode disposed on the gate insulating layer, and a source electrode and a drain electrode disposed on the gate insulating layer, the gate electrode includes a first conductive layer and a second conductive layers, the first conductive layer includes a material having a lower reflectivity than the second conductive layer, a first dummy conductive layer is disposed between the gate insulating layer and the drain electrode, the first dummy conductive layer is spaced apart from the semiconductor layer, and the drain electrode is in direct contact with the semiconductor layer.

In accordance with one or more aspects of the present disclosure, a display device may comprise a substrate, a display area including a plurality of sub-pixels, and a non-display area outside the display area, wherein each of the plurality of sub-pixels includes a transistor disposed on the substrate, the transistor includes a gate insulating layer disposed on the substrate, a gate electrode disposed on the gate insulating layer, and a source electrode and a drain electrode disposed on the gate insulating layer, the gate electrode includes a first conductive layer disposed on the gate insulating layer and a second conductive layer disposed on the first conductive layer, the first conductive layer includes a material having a lower reflectivity than the second conductive layer, and a first dummy conductive layer is disposed between the gate insulating layer and the drain electrode and is spaced apart from the first and second conductive layers.

In accordance with one or more aspects of the present disclosure, a method of manufacturing a display device may be provided. The display device may include sub-pixels in a display area, wherein each of the sub-pixels includes a transistor. The method may comprise providing a substrate, providing a semiconductor layer of the transistor on the substrate, providing a gate insulating layer on the semiconductor layer, providing a first conductive material on the gate insulating layer, providing a second conductive material on the first conductive material, and etching the first and second conductive materials. Etching the first and second conductive materials may form a gate electrode comprising a first conductive layer and a second conductive layer of the transistor and simultaneously form a first dummy conductive layer that is spaced apart from the first and second conductive layers, and the first conductive material may include a material having a lower reflectivity than the second conductive material.

Other apparatuses, methods, features and advantages will be, or will become, apparent to one with skill in the art upon examination of the drawings and detailed description herein. It is intended that all such apparatuses, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a plan view of a display device according to an example embodiment of the present disclosure.

FIG. 2 is a plan view of one sub-pixel according to an example embodiment of the present disclosure.

FIG. 3 is an example of a cross-sectional view taken along the line I-I′ of FIG. 2.

FIGS. 4A to 4F are cross-sectional views illustrating a process of manufacturing a display device according to an example embodiment of the present disclosure.

FIG. 5 is a plan view of a display device according to another example embodiment of the present disclosure.

FIG. 6 is an example of a cross-sectional view taken along line II-II′ of FIG. 5.

FIG. 7 is a plan view of a process of manufacturing a display device according to an example embodiment of the present disclosure.

FIG. 8 is an example of an enlarged plan view of a partial area of FIG. 7.

FIG. 9 is an example of a cross-sectional view taken along line III-III′ of FIG. 8.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Moreover, at least a portion (or a part) of an element can represent (i) a portion (or a part) of the element, (ii) one or more portions (or parts) of the element, or (iii) the element, or the entirety of the element. A phrase that a plurality of first elements are connected to a plurality of second elements may describe, for example, that at least a part (or one or more first elements) of a plurality of first elements are connected to at least a part (or one or more second elements) of a plurality of second elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two. In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

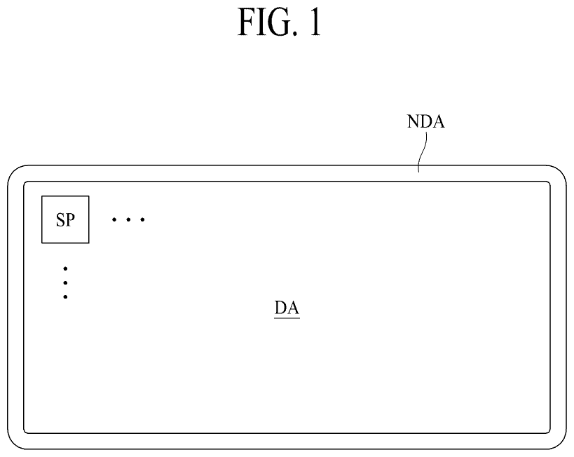

FIG. 1 is a plan view of a display device according to an example embodiment of the present disclosure.

The display device may include a display area DA and a non-display area NDA surrounding the display area DA. The display area DA is an area in which an image may be displayed, and the non-display area NDA is an area in which an image is not displayed.

A plurality of sub-pixels SP and a plurality of signal lines for driving the plurality of sub-pixels SP may be disposed in the display area DA. The plurality of signal lines may include a plurality of data lines and a plurality of gate lines.

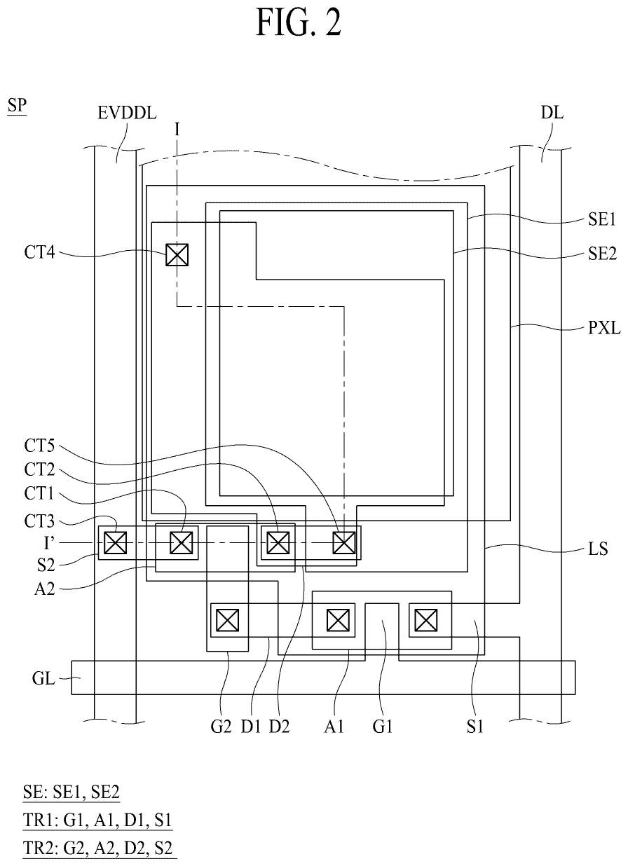

FIG. 2 is a plan view of one sub-pixel SP according to an example embodiment of the present disclosure.

The sub-pixel SP may be divided by a gate line GL and a high-potential voltage line EVDDL crossing the gate line GL.

The high-potential voltage line EVDDL may supply a high-potential voltage EVDD to the light emitting device. The gate line GL may supply a scan signal to a first transistor TR1, and a data line DL may supply a data voltage to the first transistor TR1.

The sub-pixel SP may include a light blocking layer LS, the first thin film transistor TR1, a second thin film transistor TR2, a storage capacitor Cst, and a pixel electrode PXL.

The light blocking layer LS may be disposed on a substrate SUB. The light blocking layer LS may be formed of a conductive material capable of blocking light. Accordingly, the light blocking layer LS may prevent external light from penetrating into semiconductor layers A1 and A2 of the first and second thin film transistors TR1 and TR2. The light blocking layer LS may have the same structure as any one of the high-potential voltage line EVDDL, the gate line GL, and the data line DL, but is not limited thereto.

The first thin film transistor TR1 may be disposed on the light blocking layer LS. The first thin film transistor TR1 may include a gate electrode G1, a semiconductor layer A1, a source electrode S1, and a drain electrode D1.

The semiconductor layer A1 of the first thin film transistor TR1 may be disposed on the light blocking layer LS, and may overlap the light blocking layer LS. Also, an area of the light blocking layer LS may be larger than an area of the semiconductor layer A1 of the first thin film transistor TR1. Accordingly, the light blocking layer LS may block external light penetrating into the semiconductor layer A1 of the first thin film transistor TR1.

The semiconductor layer A1 of the first thin film transistor TR1 may include a poly-silicon semiconductor or an oxide semiconductor. In addition, when the semiconductor layer A1 of the first thin film transistor TR1 includes an oxide semiconductor, the semiconductor layer A1 may include at least one oxide of indium-gallium-zinc-oxide (IGZO), indium-gallium-tin-oxide (IGTO), and indium-gallium-oxide (IGO).

The gate electrode G1 of the first thin film transistor TR1 may be disposed on the semiconductor layer A1. The gate electrode G1 of the first thin film transistor TR1 may receive a scan signal from the gate line GL. Also, the gate electrode G1 of the first thin film transistor TR1 may be formed by being branched from the gate line GL.

The source electrode S1 and the drain electrode D1 of the first thin film transistor TR1 may be disposed on the semiconductor layer A1 while facing each other. Each of the source electrode S1 and the drain electrode D1 of the first thin film transistor TR1 may be connected with the semiconductor layer A1 of the first thin film transistor TR1 through a contact hole. Also, the source electrode S1 of the first thin film transistor TR1 may be formed by being branched from the data line DL.

The second thin film transistor TR2 may be disposed on the light blocking layer LS. The second thin film transistor TR2 may include a gate electrode G2, a semiconductor layer A2, a source electrode S2, and a drain electrode D2.

The semiconductor layer A2 of the second thin film transistor TR2 may be disposed on the light blocking layer LS, and may overlap the light blocking layer LS. Also, the area of the light blocking layer LS may be larger than an area of the semiconductor layer A2 of the second thin film transistor TR2. Accordingly, the light blocking layer LS may block external light penetrating into the semiconductor layer A2 of the second thin film transistor TR2.

The gate electrode G2 of the second thin film transistor TR2 may be disposed on the semiconductor layer A2. The gate electrode G2 of the second thin film transistor TR2 may be connected with the drain electrode D1 of the first thin film transistor TR1 through the contact hole. That is, when the first thin film transistor TR1 is turned on, the data voltage supplied through the data line DL may be supplied to the gate electrode G2 of the second thin film transistor TR2.

The source electrode S2 and the drain electrode D2 of the second thin film transistor TR2 may be disposed on the semiconductor layer A2 while facing each other. The source electrode S2 of the second thin film transistor TR2 may be connected with the high-potential voltage line EVDDL through a first contact hole CT1, and may be connected with the semiconductor layer A2 of the second thin film transistor TR2 through a third contact hole CT3. Also, the drain electrode D2 of the second thin film transistor TR2 may be connected with the semiconductor layer A2 of the second thin film transistor TR2 through a second contact hole CT2, and may be connected with the pixel electrode PXL through a fifth contact hole CT5. That is, when the second thin film transistor TR2 is turned on, the high-potential voltage supplied through the high potential voltage line EVDDL may be supplied to the pixel electrode PXL.

The pixel electrode PXL may be disposed on the first and second thin film transistors TR1 and TR2. Also, the light blocking layer LS may extend to an area overlapping the pixel electrode PXL. The pixel electrode PXL may function as an anode of a light emitting device. Also, the pixel electrode PXL may include a transparent conductive material such as an indium tin oxide (ITO) or an indium zinc oxide (IZO), and the like, or an alloy thereof. Alternatively, the pixel electrode PXL may include a metal material such as aluminum (Al), silver (Ag), copper (Cu), molybdenum (Mo), titanium (Ti), tungsten (W), or chromium (Cr), and the like, or an alloy thereof.

The storage capacitor Cst may be disposed on the light blocking layer LS. A driving current may flow through the second thin film transistor TR2 according to a voltage stored in the storage capacitor Cst.

The storage capacitor Cst may include a plurality of sub-electrodes SE. The plurality of sub-electrodes SE may include first and second sub-electrodes SE1 and SE2. The first sub-electrode SE1 is formed through the same process as the semiconductor layer A2 of the second thin film transistor TR2, and may be formed of the same material. The first sub-electrode SE1 may be separated from the semiconductor layer A2 of the second thin film transistor TR2, or may be formed continuously. Also, the second sub-electrode SE2 is formed through the same process as the gate electrode G2 of the second thin film transistor TR2, and may be formed of the same material.

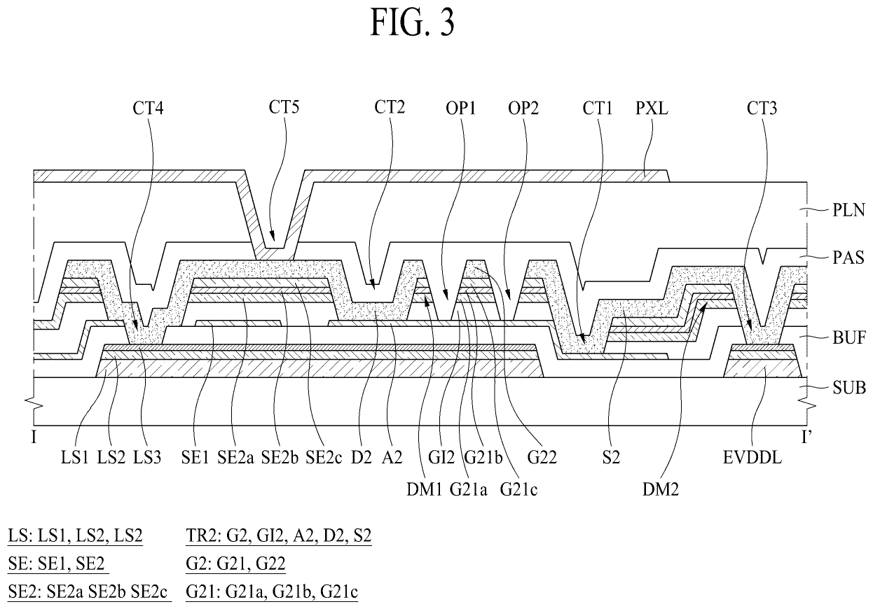

FIG. 3 is an example of a cross-sectional view taken along line I-I′ of FIG. 2. That is, FIG. 3 is an example of a cross-sectional view of the high-potential voltage line EVDDL, the second thin film transistor TR2, and the storage capacitor Cst.

Referring to FIG. 3, one sub-pixel SP according to an example embodiment of the present disclosure may include a substrate SUB, a light blocking layer LS, a buffer layer BUF, a second thin film transistor TR2, a passivation layer PAS, a planarization layer PLN, and a pixel electrode PXL.

The substrate SUB may be made of glass or plastic, but is not limited thereto. The display device according to an example embodiment of the present disclosure may be configured in a top emission type in which the emitted light is emitted upward. Accordingly, as the material of the substrate SUB, not only a transparent material but also an opaque material may be used.

The light blocking layer LS may be disposed on the substrate SUB. As described above, the light blocking layer LS may be formed of the conductive material capable of blocking light, and may prevent external light from penetrating into the semiconductor layer A2 of the second thin film transistor TR2.

The light blocking layer LS may include a lower light blocking layer LS1, a central light blocking layer LS2, and an upper light blocking layer LS3.

The lower light blocking layer LS1 may be disposed on the substrate SUB. The lower light blocking layer LS1 may be formed of a material having a reflectivity that is lower than those (or a reflectivity of a material in each) of the central light blocking layer LS2 and the upper light blocking layer LS3. For example, the lower light blocking layer LS1 may include tungsten oxide (WOx).

The central light blocking layer LS2 may be disposed on the lower light blocking layer LS1, and the upper light blocking layer LS3 may be disposed on the central light blocking layer LS2. The central light blocking layer LS2 may cover an entire upper surface of the lower light blocking layer LS1, and the upper light blocking layer LS3 may cover an entire upper surface of the central light blocking layer LS2. Also, the central light blocking layer LS2 and the upper light blocking layer LS3 may include a metal material such as aluminum (Al), silver (Ag), copper (Cu), molybdenum (Mo), titanium (Ti), tungsten (W), or an alloy thereof. In one or more examples, each of the central light blocking layer LS2 and the upper light blocking layer LS3 may include one or more metal materials of aluminum (Al), silver (Ag), copper (Cu), molybdenum (Mo), titanium (Ti), tungsten (W), chromium (Cr), or an alloy including Al, Ag, Cu, Mo, Ti, W or Cr. The upper light blocking layer LS3 may include a material having a lower oxidation degree than that of the central light blocking layer LS2 and easy adhesion to other conductive layers. For example, the central light blocking layer LS2 may include copper (Cu), and the upper light blocking layer LS3 may include molybdenum-titanium (MoTi).

The high-potential voltage line EVDDL may be disposed on the substrate SUB. The high-potential voltage line EVDDL may be formed through the same process as the light blocking layer LS, and may be formed of the same material. That is, in FIG. 3, since the light blocking layer LS has a stacked structure including the lower light blocking layer LS1, the central light blocking layer LS2, and the upper light blocking layer LS3, the high-potential voltage line EVDDL may also have a stacked structure including a lower layer, a central layer, and an upper layer.

The buffer layer BUF may be disposed on the light blocking layer LS and the high-potential voltage line EVDDL. The buffer layer BUF may cover the light blocking layer LS and the high-potential voltage line EVDDL. The buffer layer BUF may be formed of an inorganic insulating material such as silicon oxide (SiOx), silicon nitride (SiNx), silicon oxynitride (SiOxNy), or the like.

The second thin film transistor TR2 may be disposed on the buffer layer BUF. The second thin film transistor TR2 and the light blocking layer LS may be electrically separated by the buffer layer BUF. The second thin film transistor TR2 may be disposed in an area overlapping the light blocking layer LS.

As described above, the second thin film transistor TR2 may include a gate electrode G2, a semiconductor layer A2, a source electrode S2, and a drain electrode D2.

The semiconductor layer A2 of the second thin film transistor TR2 may be disposed on the buffer layer BUF. Also, a gate insulating layer GI2 may be disposed between the semiconductor layer A2 and the gate electrode G2 of the second thin film transistor TR2. he gate insulating layer GI2 may be formed of a single layer of silicon nitride (SiNx) or silicon oxide (SiOx), or multiple layers thereof.

The gate electrode G2 may include a first conductive layer and a second conductive layer G21 and G22.

The first conductive layer G21 may be disposed on the gate insulation layer GI2. The first conductive layer G21 may include a lower conductive layer G21a, a central conductive layer G21b, and an upper conductive layer G21c.

The lower conductive layer G21a may be disposed on the gate insulating layer GI2. The lower conductive layer G21a may cover an upper surface of the gate insulating layer GI2. The lower conductive layer G21a may be formed of a material having a reflectivity that is lower than those (or a reflectivity of a material in each) of the central conductive layer G21b and the upper conductive layer G21c. For example, the lower conductive layer G21a may include tungsten oxide (WOx). Accordingly, when external light is penetrated, unnecessary reflection inside the display device may be minimized.

The central conductive layer G21b may be disposed on the lower conductive layer G21b, and the upper conductive layer G21c may be disposed on the central conductive layer G21b. The central conductive layer G21b may cover an entire upper surface of the lower conductive layer G21b, and the upper conductive layer G21c may cover an entire upper surface of the central conductive layer G21b.

The central conductive layer G21b and the upper conductive layer G21c may include metal materials such as aluminum (Al), silver (Ag), copper (Cu), molybdenum (Mo), titanium (Ti), tungsten (W), or chromium (Cr), or alloys thereof. For example, the central conductive layer G21b may include molybdenum-titanium (MoTi), and the upper conductive layer G21c may include copper (Cu).

The second conductive layer G22 may be disposed on the first conductive layer G21. The second conductive layer G22 may cover an entire upper surface of the first conductive layer G21. The second conductive layer G22 may include a metal material such as aluminum (Al), silver (Ag), copper (Cu), molybdenum (Mo), titanium (Ti), tungsten (W), or chromium (Cr), or an alloy thereof.

In one or more examples, each of the central conductive layer G21b, the upper conductive layer G21c, and the second conductive layer G22 may include one or more metal materials of aluminum (Al), silver (Ag), copper (Cu), molybdenum (Mo), titanium (Ti), tungsten (W), chromium (Cr), or an alloy including Al, Ag, Cu, Mo, Ti, W or Cr.

The source electrode S2 and the drain electrode D2 may be disposed on the gate insulating layer GI. The source electrode S2 and the drain electrode D2 may be formed through the same process as the second conductive layer G22 of the gate electrode G2, and may include the same material.

The gate electrode G2 and the drain electrode D2 disposed on the gate insulating layer GI2 may be separated by a first opening OP1. Also, the gate electrode G2 and the source electrode S2 disposed on the gate insulating layer GI2 may be separated by a second opening OP2.

In this case, a first dummy conductive layer DM1 may be disposed between the drain electrode D2 and the gate insulating layer GI. Also, a second dummy conductive layer DM2 may be disposed between the source electrode S2 and the gate insulating layer GI. The first and second dummy conductive layers DM1 and DM2 may be conductive layers remaining on the gate insulating layer GI in the process of forming the first conductive layer G21 of the gate electrode G2. That is, the first and second dummy conductive layers DM1 and DM2 (or each of them) may have the same structure as that of the first conductive layer G21 of the gate electrode G2. Further, in an example, each of the first and second dummy conductive layers DM1 and DM2 may be spaced apart from certain layers and electrodes (e.g., G2, G21, G22, and SE1). In an example, each of the first and second dummy conductive layers DM1 and DM2 may be spaced apart (or separated) from at least a portion of some of certain layers and electrodes (e.g., G2, G21, G22, and SE1). In some examples, each of the first and second dummy conductive layers DM1 and DM2 may be electrically isolated from certain layers and electrodes (e.g., G2, G21, G22, and SE1).

The source electrode S2 may be in direct contact with the semiconductor layer A2 through the first contact hole CT1 formed in the buffer layer BUF, the gate insulating layer GI2, and the second dummy conductive layer DM2. That is, the second dummy conductive layer DM2 may be spaced apart from the semiconductor layer A2. Also, the source electrode S2 may further extend to the outer periphery of the semiconductor layer A2 and may be connected with the high-potential voltage line EVDDL. That is, the source electrode S2 may be in direct contact with the high-potential voltage line EVDDL through the third contact hole CT3 formed in the buffer layer BUF, the gate insulating layer GI2, and the second dummy conductive layer DM2. Also, the second dummy conductive layer DM2 may be spaced apart from the high-potential voltage line EVDDL.

The drain electrode D2 may be in direct contact with the semiconductor layer A2 through the second contact hole CT2 formed in the buffer layer BUF, the gate insulating layer GI2, and the first dummy conductive layer DM1. That is, the first dummy conductive layer DM1 may be spaced apart from the semiconductor layer A2. Also, the drain electrode D2 may further extend to the outer periphery of the semiconductor layer A2 and may be connected with the light blocking layer LS. That is, the drain electrode D2 may be in direct contact with the light blocking layer LS through the fourth contact hole CT4 formed in the buffer layer BUF, the gate insulating layer GI2, and the first dummy conductive layer DM1. Also, the first dummy conductive layer DM1 may be spaced apart from the light blocking layer LS.

The storage capacitor Cst may be disposed on the light blocking layer LS. As described above, the storage capacitor Cst may include first and second sub-electrodes SE1 and SE2.

The first sub-electrode SE1 may be disposed on the light blocking layer LS, and may overlap the light blocking layer LS. The first sub-electrode SE1 may be formed through the same process as the semiconductor layer A2 of the second thin film transistor TR2, and may be formed of the same material.

The second sub-electrode SE2 is formed through the same process as the first conductive layer G21 of the gate electrode G2 of the second thin film transistor TR2, and may be formed of the same material. That is, since the first conductive layer G21 of the gate electrode G2 has a structure in which the lower conductive layer G21a, the central conductive layer G21b, and the upper conductive layer G21c are stacked, the second sub-electrode SE2 may also have a structure in which a lower conductive layer SE2a, a central conductive layer SE2b, and an upper conductive layer SE2c are stacked.

Since the gate insulating layer GI2 of the second thin film transistor TR2 is disposed between the first and second sub-electrodes SE1 and SE2, the first and second sub-electrodes SE1 and SE2 and the gate insulating layer GI2 may function as a capacitor. Meanwhile, since the buffer layer BUF is disposed between the first sub-electrode SE1 and the light blocking layer LS, the first sub-electrode SE1, the light blocking layer LS, and the buffer layer BUF may also function as a capacitor. Accordingly, a capacity of the storage capacitor Cst may be further increased.

The passivation layer PAS may be disposed on the second thin film transistor TR2 and the storage capacitor Cst. The passivation layer PAS may compensate for a step difference caused by the second thin film transistor TR2 and the storage capacitor Cst. Also, the passivation layer PAS may fill in the first and second openings OP1 and OP2. Accordingly, the gate electrode G2, the source electrode S2, and the drain electrode D2 of the second thin film transistor TR2 may be stably separated from each other.

The passivation layer PAS may be formed of an inorganic insulating material such as silicon oxide (SiOx), silicon nitride (SiNx), or silicon oxynitride (SiOxNy).

The planarization layer PLN may be disposed on the passivation layer PAS. The planarization layer PLN may be formed of an organic insulating material such as an acrylic resin, an epoxy resin, a phenolic resin, a polyamide resin, or a polyimide resin.

The pixel electrode PXL is disposed on the planarization layer PLN, and may function as an anode of the display device. The pixel electrode PXL may be electrically connected with the drain electrode D2 of the second thin film transistor TR2 through the fifth contact hole CT5 formed in the passivation layer PAS and the planarization layer PLN.

FIG. 3 shows that the fifth contact hole CT5 overlaps the second sub-electrode SE2, but the present disclosure is not limited thereto. For example, the fifth contact hole CT5 may overlap the second contact hole CT2 or the fourth contact hole CT4.

In one or more aspects, the present disclosure provides the gate electrode including the plurality of conductive layers. Specifically, the gate electrode G2 may include the first conductive layer G21 including the lower conductive layer G21a, the central conductive layer G21b, and the upper conductive layer G21c, and the second conductive layer G22 consisting of one layer. In this case, the source electrode S2 and the drain electrode D2 are formed of the same material as the second conductive layer G22 of the gate electrode G2, and may be in direct contact with and electrically connected with other conductive layers.

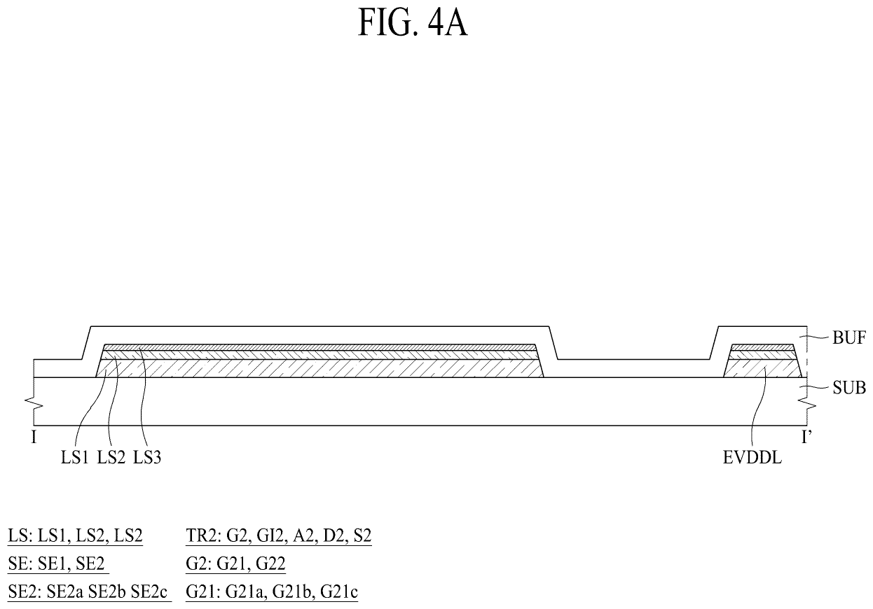

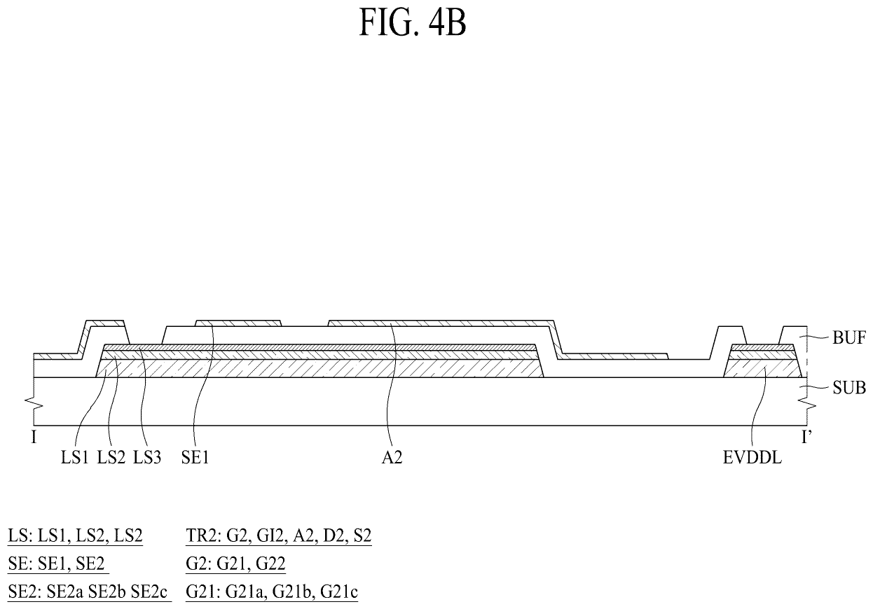

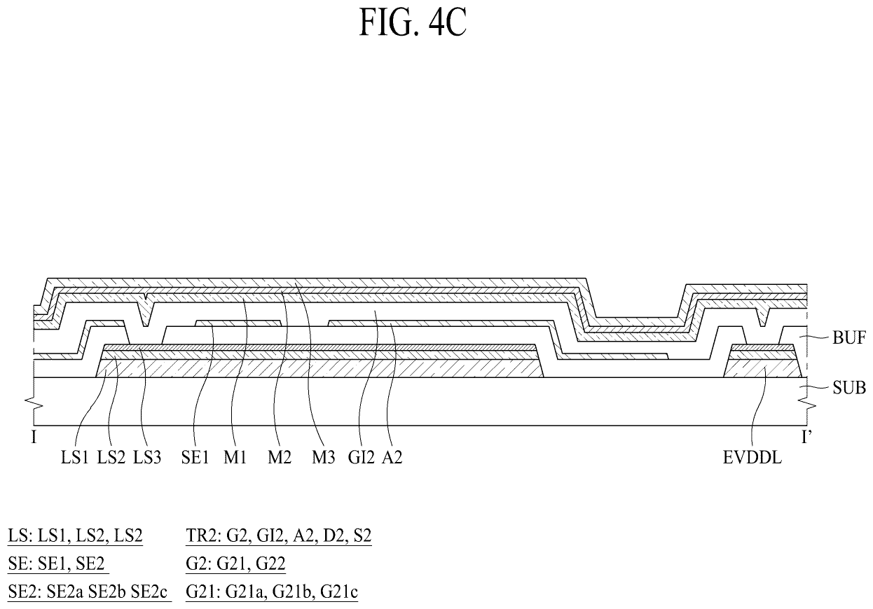

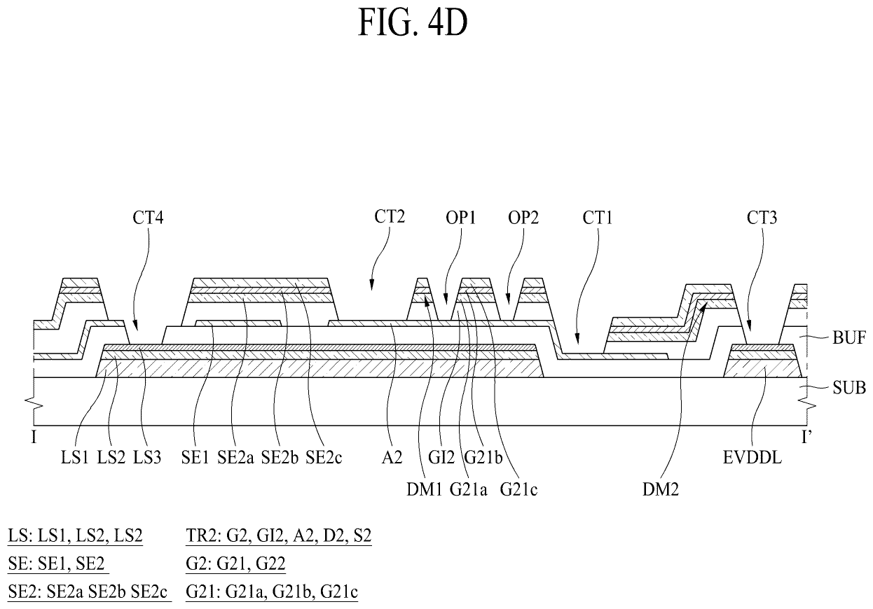

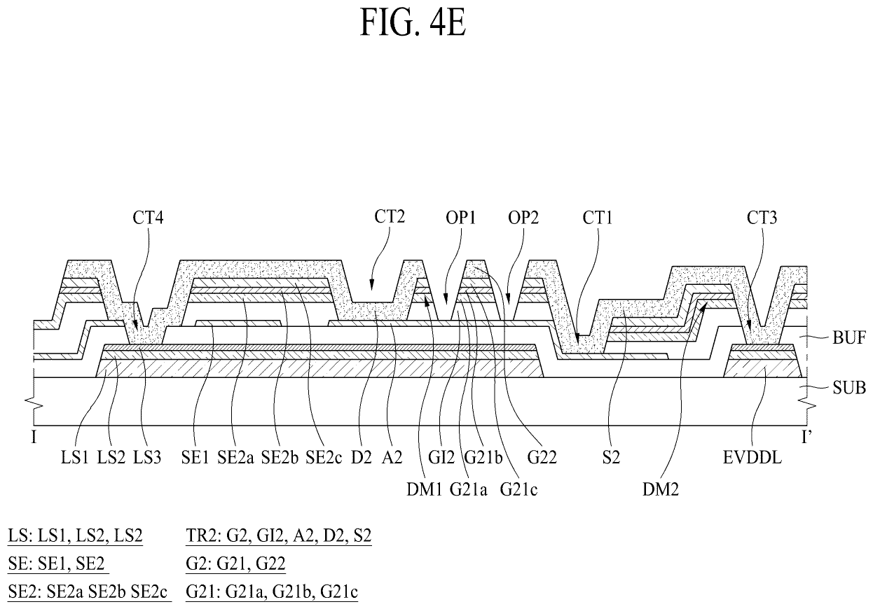

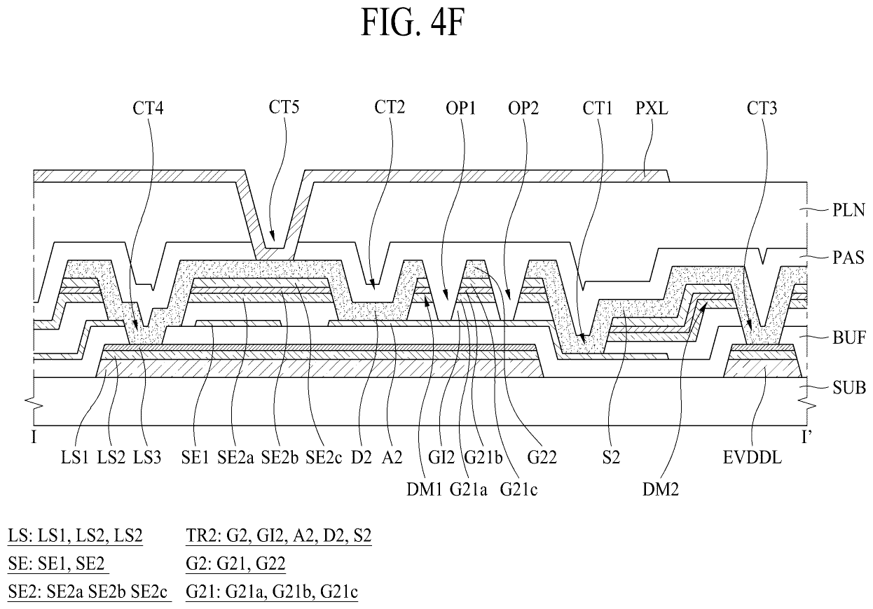

FIGS. 4A to 4F are cross-sectional views illustrating a process of manufacturing of a display device according to an example embodiment of the present disclosure. FIGS. 4A to 4F illustrate a process based on a cross-sectional view of FIG. 3.

Referring to FIG. 4A, a light blocking layer LS and a high-potential voltage line EVDDL may be formed on a substrate SUB. The light blocking layer LS and the high potential voltage line EVDDL may be formed through the same process and may be formed of the same material. That is, in FIG. 3, since the light blocking layer LS has a stacked structure including a lower light blocking layer LS1, a central light blocking layer LS2, and an upper light blocking layer LS3, the high potential voltage line EVDDL may also have a stacked structure including a lower layer, a central layer, and an upper layer.

A buffer layer BUF may be formed on the light blocking layer LS and the high potential voltage line EVDDL. The buffer layer BUF may cover the light blocking layer LS and the high potential voltage line EVDDL. The buffer layer BUF may be formed of an inorganic insulating material such as silicon oxide (SiOx), silicon nitride (SiNx), silicon oxynitride (SiOxNy).

Referring to FIG. 4B, a semiconductor layer A2 of a second thin film transistor TR2 and a first sub-electrode SE1 may be formed on the buffer layer BUF. In detail, a semiconductor material may be deposited on an entire surface of the substrate SUB. The semiconductor material may include a poly-silicon semiconductor or an oxide semiconductor. In addition, when the semiconductor material includes an oxide semiconductor, at least one oxide of indium-gallium-zinc-oxide (IGZO), indium-zinc-oxide (IZO), indium-gallium-tin-oxide (IGTO), and indium-gallium-oxide (IGO) may be included.

In addition, a partial area of the deposited semiconductor material may be etched. After etching, some area of the semiconductor materials remaining may become the semiconductor layer A2 of the second thin film transistor TR2, and the others may become the first sub-electrode SE1. That is, the semiconductor layer A2 of the second thin film transistor TR2 and the first sub-electrode SE1 may be formed through the same process and may be formed of the same material.

Referring to FIG. 4C, a gate insulating layer GI2 may be formed on the entire surface of the substrate SUB. The gate insulating layer GI2 may consist of a single layer of silicon nitride (SiNx) or silicon oxide (SiOx), or multiple layers thereof.

In addition, a first conductive material M1, a second conductive material M2, and a third conductive material M3 may be sequentially deposited on the gate insulating layer GI2.

The first conductive material M1 may be a material having a reflectivity that is lower than those (or a reflectivity of a material of each) of the second conductive material M2 and the third conductive material M3. For example, the first conductive material M1 may be tungsten oxide (WOx). Accordingly, when external light is penetrated, unnecessary reflection in the display device may be minimized.

The second and third conductive materials M2 and M3 may include metal materials such as aluminum (Al), silver (Ag), copper (Cu), molybdenum (Mo), titanium (Ti), tungsten (W), or chromium (Cr), or alloys thereof. In one or more examples, each of the second and third conductive materials M2 and M3 may include one or more metal materials of aluminum (Al), silver (Ag), copper (Cu), molybdenum (Mo), titanium (Ti), tungsten (W), chromium (Cr), or an alloy including Al, Ag, Cu, Mo, Ti, W or Cr. For example, the second conductive material M2 may be molybdenum-titanium (MoTi), and the third conductive material M3 may be copper (Cu).

Referring to FIG. 4D, the gate insulating layer GI2 and the first to third conductive materials M1-M3 may be etched. In detail, the first to third conductive materials M1-M3 may be simultaneously etched through a wet etching process, and the gate insulating layer GI2 may be etched through a dry etching process. The wet etching process may use a galvanic etchant, but is not limited thereto.

Generally, a material having a low reflectivity has a low corrosion rate due to an etchant compared to a material having a high reflectivity. Accordingly, when the material having a low reflectivity is wet-etched alone, there is a high possibility that an unnecessary material layer remains on the substrate. That is, a residual film may be generated in the display device, and the display device may not be driven normally.

However, in one or more aspects, the present disclosure provides simultaneous etching of the first conductive material M1, which is a material having low reflectivity, and the second and third conductive materials M2 and M3, which are materials having a high reflectivity. That is, as the second and third conductive materials M2 and M3 that react first with the etchant are normally removed, the first conductive material M1 may also be removed from the substrate SUB. Therefore, the possibility of generating the residual film in the display device may be minimized. In addition, since the first conductive material M1 is the material having low reflectivity, a function of reducing reflectivity due to external light of the display device may be maintained.

First to fourth contact holes CT1-CT4, a second sub-electrode SE2, a first conductive layer G2, and a dummy conductive layer DM may be formed by etching the gate insulating layer GI2 and the first to third conductive materials M1-M3.

The first and second contact holes CT1 and CT2 may expose a portion of an upper surface of the semiconductor layer A2. Also, the third contact hole CT3 may expose a portion of an upper surface of the high potential voltage line EVDDL, and the fourth contact hole CT4 may expose a portion of an upper surface of the light blocking layer LS.

Since the second sub-electrode SE2, the first conductive layer G2, and the dummy conductive layer DM are formed through the same process, they may have the same structure.

Specifically, the first conductive layer G2 may include a lower conductive layer G21a formed of the first conductive material M1, a central conductive layer G21b formed of the second conductive material M2, and an upper conductive layer G21c formed of the third conductive material M3. Furthermore, the second sub-electrode SE2 may include a lower conductive layer SE2a formed of the first conductive material M1, a central conductive layer SE2b formed of the second conductive material M2, and an upper conductive layer SE2c formed of the third conductive material M3.

Referring to FIG. 4E, a second conductive layer G22, a source electrode S2, and a drain electrode D2 may be formed. In detail, after one conductive material is deposited on the substrate SUB, an area overlapping the first and second openings OP1 and OP2 may be etched.

The second conductive layer G22 and the drain electrode D2 disposed on the gate insulating layer GI2 may be separated from each other by the first opening OP1. Also, the second conductive layer G22 disposed on the gate insulating layer GI2 and the source electrode S2 may be separated from each other by the second opening OP2. Accordingly, the gate electrode G2 may have a structure in which the first and second conductive layers G21 and G22 are stacked.

The source electrode S2 may be in direct contact with the semiconductor layer A2 through the first contact hole CT1. Also, the source electrode S2 may be in direct contact with the high potential voltage line EVDDL through the third contact hole CT3. The drain electrode D2 may be in direct contact with the semiconductor layer A2 through the second contact hole CT2. Also, the drain electrode D2 may be in direct contact with the light blocking layer LS through the fourth contact hole CT4.

That is, in the contact hole, the source electrode S2 and the drain electrode D2 may be in direct contact with and electrically connected with another conductive layer. In addition, the dummy layer DM may not be disposed in a contact area between the source electrode S2 and another conductive layer, and may not be disposed in a contact area between drain electrode D2 and another conductive layer. Accordingly, the source electrode S2 and the drain electrode D2 may be stably connected with another conductive layer.

Referring to FIG. 4F, a passivation layer PAS may be formed on the second thin film transistor TR2 and the storage capacitor Cst. The passivation layer PAS may fill in the first and second openings OP1 and OP2. Also, the passivation layer PAS may be formed of an inorganic insulating material, such as silicon oxide (SiOx), silicon nitride (SiNx), silicon oxynitride (SiOxNy), or the like.

The planarization layer PLN may be disposed on the passivation layer PAS. The planarization layer PLN may be formed of an organic insulating material such as an acrylic resin, an epoxy resin, a phenolic resin, a polyamide resin, or a polyimide resin.

The pixel electrode PXL is disposed on the planarization layer PLN and may function as an anode of the display device. The pixel electrode PXL may be electrically connected with the drain electrode D2 through the fifth contact hole CT5.

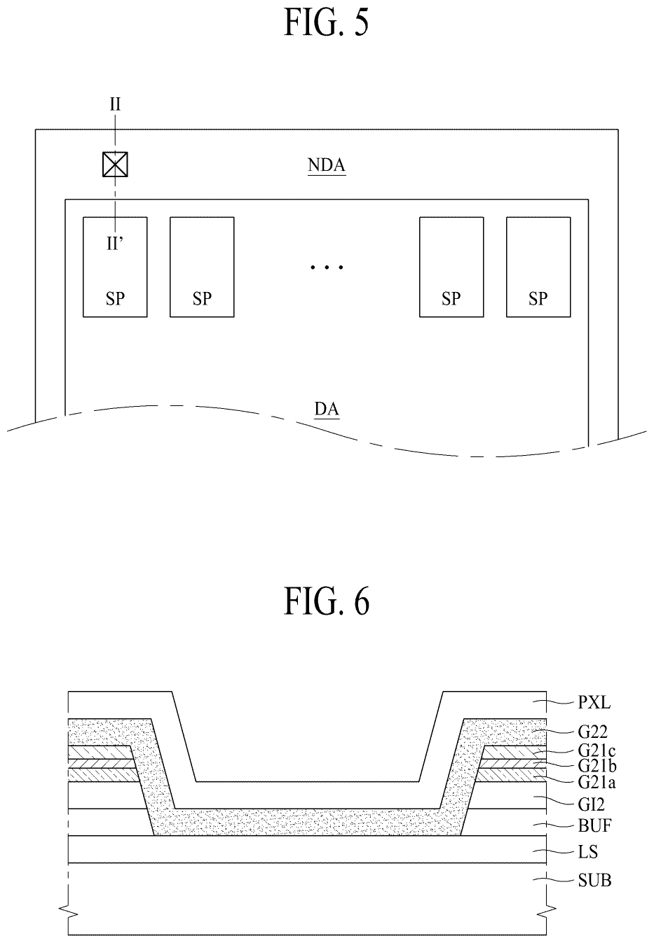

FIG. 5 is a plan view of a display device according to another example embodiment of the present disclosure. Also, FIG. 6 is an example of a cross-sectional view taken along line II-II′ of FIG. 5.

As described above in FIG. 1, in one or more aspects, the display device of the present disclosure may include a display area DA and a non-display area NDA surrounding the display area DA. Also, a plurality of sub-pixels SP may be disposed in the display area DA.

In FIGS. 2 and 3, it is illustrated that the drain electrode D2 formed of the second conductive layer G22 and the light blocking layer LS are connected with through the fourth contact hole CT4 disposed in the sub-pixel SP, but is not limited thereto. That is, as shown in FIGS. 5 and 6, a contact hole may also be formed in the outside the sub-pixel SP or in the non-display area NDA.

As described above with reference to FIGS. 2 and 3, the buffer layer BUF, the gate insulating layer GI, and the first conductive layer G21 may be etched to form a contact hole. And, through the contact hole, the light blocking layer LS and the second conductive layer G22 may be in direct contact with each other. Also, the pixel electrode PXL may be disposed on the second conductive layer G22 to protect the second conductive layer G22 from the outside.

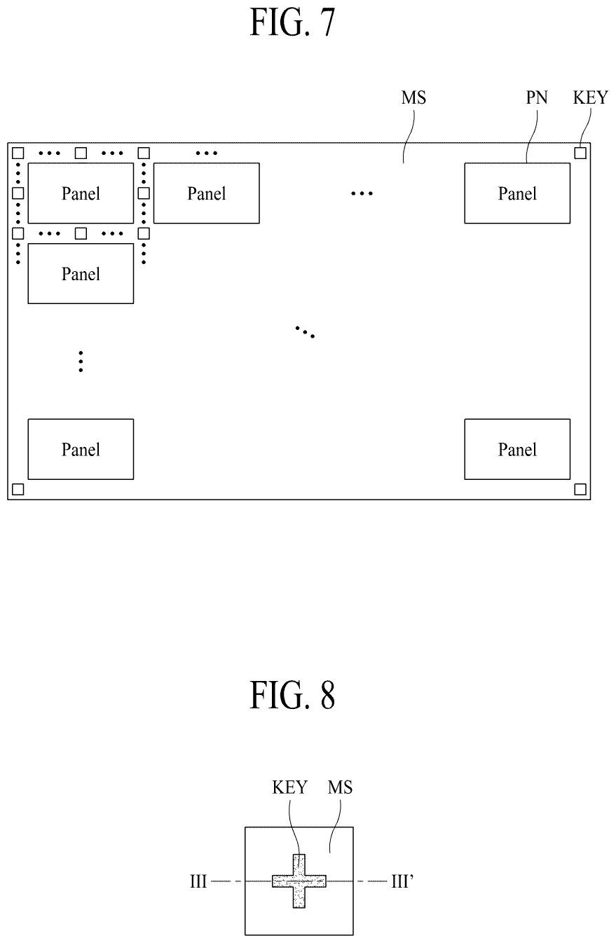

FIG. 7 is a plan view of a process of manufacturing a display panel PNL of a display device according to an example embodiment of the present disclosure.

Referring to FIG. 7, after forming a plurality of display panels PNL on a mother substrate MS, each of the display panels PNL may be finally separated. Accordingly, the display panel PNL of the display device may be formed.

The manufacturing process of the display panel PNL may include a deposition process, a photolithography process, or a scribing process. In addition, an alignment key KEY for alignment may be formed on the mother substrate MS for each process. The alignment key KEY may provide position information so that the display panel PNL can be accurately aligned in the display device. In addition, the display panel PNL may provide cutting position information in a scribing process.

Referring to FIG. 8, the alignment key KEY may be formed in a cross shape, but is not limited thereto. For example, the alignment key KEY may have various shapes such as a circle and a polygon.

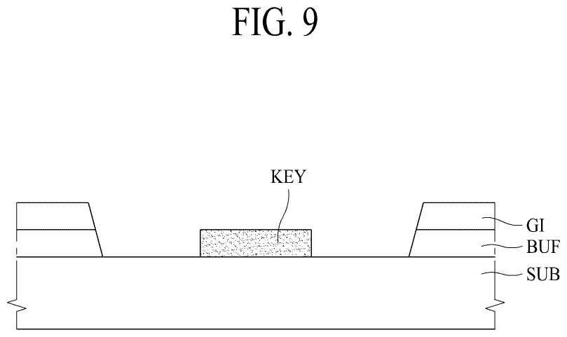

FIG. 9 is an example of a cross-sectional view taken along line III-III′ of FIG. 8. That is, it illustrates a cross-section of the alignment key KEY.

Referring to FIG. 9, the alignment key KEY may be formed on an upper surface of the substrate SUB. The alignment key KEY may be disposed in the non-display area NDA. In this case, the alignment key KEY is formed through the same process as the second conductive layer G22, and may include the same material. In this case, no other material layer may be disposed between the alignment key KEY and the substrate SUB. That is, after an insulating layer and the first conductive layer G21 are removed, the second conductive layer G22 directly disposed on the upper surface of the substrate SUB may be used as the alignment key KEY.

When the alignment key KEY includes a material having a low reflectivity, there is a possibility that various devices may inaccurately recognize the alignment key KEY. In this case, exposure and development processes during deposition or photolithography may be performed without precision. Accordingly, the quality and reliability of the display device may be reduced, and visibility characteristics such as color reproduction and contrast ratio may be reduced.

However, in one or more aspects, in the present disclosure, after removing the first conductive layer G21 having a relatively low reflectivity, only the second conductive layer G22 may be used as the alignment key KEY. Accordingly, it is possible to improve the alignment key KEY recognition rate of various devices.

In one or more examples, when a first component (e.g., a first layer or electrode) has a same structure as a second component (e.g., a second layer or electrode), the first component may be formed of the same material(s), of the same thickness and at the same time as the second component. For example, the first sub-electrode SE1 may be formed of the same material(s), of the same thickness and at the same time as the semiconductor layer A2. For example, the second sub-electrode SE2 may be formed of the same material(s), of the same thickness and at the same time as the first conductive layer G21. For example, each of the first and second dummy conductive layer DM1 and DM2 may be formed of the same material(s), of the same thickness and at the same time as the first conductive layer G21. For example, the alignment keys KEY may be formed of the same material(s), of the same thickness and at the same time as the second conductive layer G22.

In one or more aspects, when a first layer includes a material having a lower reflectivity than a material of a second layer, this can be described, for example, as follows: the first layer includes a material having a lower reflectivity than the second layer; or the first layer has a lower reflectivity than the second layer.

In one or more examples, a layer may include one or more layers. In one or more examples, an electrode may include one or more electrodes. In one or more examples, a source electrode may be referred to as a drain electrode, and a drain electrode may be referred to as a source electrode.

In one or more examples, a lower conductive layer G21a may be referred to as a first conductive layer. In one or more examples, a central conductive layer G21b, an upper conductive layer G21c or a second conductive layer G22 may be referred to as a second conductive layer. In one or more examples, a second conductive material M2 or a third conductive material M3 may be referred to as a second conductive material. In one or more examples, a lower conductive layer G21a, a central conductive layer G21b and an upper conductive layer G21c may be referred to as the first, second and third conductive layers, respectively. In one or more examples, a second conductive layer G22 may be referred to as a fourth conductive layer of a gate electrode.

According to one or more aspects of the present disclosure, the following advantageous effects may be obtained.

According to one or more aspects of the present disclosure, a plurality of light conversion layers may be formed so that light efficiency may be improved, and reflectance due to external light may be reduced.

It will be apparent to those skilled in the art that the present disclosure described above is not limited by the above-described embodiments and the accompanying drawings and that various substitutions, modifications and variations can be made in the present disclosure without departing from the spirit or scope of the present disclosure. Consequently, the scope of the present disclosure is defined by the accompanying claims, and it is intended that all variations or modifications derived from the meaning, scope and equivalent concept of the claims fall within the scope of the present disclosure.

What is claimed is:

1. A display device, comprising:
a substrate;
a display area including a plurality of sub-pixels divided by a plurality of signal lines; and
a non-display area surrounding the display area,
wherein:
each of the plurality of sub-pixels includes a thin film transistor disposed on the substrate;
the thin film transistor includes a semiconductor layer disposed on the substrate, a gate insulating layer disposed on the semiconductor layer, a gate electrode disposed on the gate insulating layer, and a source electrode and a drain electrode disposed on the gate insulating layer,
the gate electrode includes a first conductive layer and a second conductive layer;
the first conductive layer includes a material having a lower reflectivity than the second conductive layer;
a first dummy conductive layer is disposed between the gate insulating layer and the drain electrode, and is spaced apart from the semiconductor layer; and
the drain electrode is in direct contact with the semiconductor layer.

2. The display device of claim 1, wherein the first conductive layer has a structure in which a lower conductive layer, a central conductive layer, and an upper conductive layer are sequentially stacked,
the second conductive layer has one conductive layer, and
the lower conductive layer comprises a material having a lower reflectivity than each of the central conductive layer, the upper conductive layer, and the second conductive layer.

3. The display device of claim 2, wherein the lower conductive layer includes tungsten oxide (WOx), and
each of the central conductive layer, the upper conductive layer, and the second conductive layer includes one or more metal materials of aluminum (Al), silver (Ag), copper (Cu), molybdenum (Mo), titanium (Ti), tungsten (W), chromium (Cr), or an alloy including Al, Ag, Cu, Mo, Ti, W or Cr.

4. The display device of claim 2, wherein the first dummy conductive layer has a same structure as the first conductive layer, and the drain electrode has a same structure as the second conductive layer.

5. The display device of claim 1, wherein through a contact hole penetrating the gate insulating layer and the first dummy conductive layer, the drain electrode is connected to the semiconductor layer for electrical connection.

6. The display device of claim 2, wherein each of the plurality of sub-pixels further includes a first sub-electrode disposed on the substrate and a second sub-electrode disposed on the first sub-electrode, and
the first sub-electrode has a same structure as the semiconductor layer, and the second sub-electrode has a same structure as the first conductive layer.

7. The display device of claim 6, wherein the drain electrode is in contact with the second sub-electrode.

8. The display device of claim 2, wherein each of the plurality of sub-pixels further includes a light blocking layer disposed between the substrate and the thin film transistor,
the light blocking layer has a structure in which a lower light blocking layer, a central light blocking layer, and an upper light blocking layer are sequentially stacked, and
the lower light blocking layer comprises a material having a lower reflectivity than each of the central light blocking layer and the upper light blocking layer.

9. The display device of claim 8, wherein the lower light blocking layer includes tungsten oxide (WOx), and
each of the central light blocking layer and the upper light blocking layer includes one or more metal materials of aluminum (Al), silver (Ag), copper (Cu), molybdenum (Mo), titanium (Ti), tungsten (W), chromium (Cr), or an alloy including Al, Ag, Cu, Mo, Ti, W or Cr.

10. The display device of claim 9, wherein through a contact hole penetrating the gate insulating layer and the first dummy conductive layer, the drain electrode is in direct contact with the light blocking layer.

11. The display device of claim 10, wherein the contact hole is disposed in the non-display area.

12. The display device of claim 2, wherein each of the plurality of sub-pixels further includes a second dummy conductive layer,
the second dummy conductive layer is disposed between the gate insulating layer and the source electrode, and has a same structure as the first conductive layer, and
the second dummy conductive layer is spaced apart from the semiconductor layer, and the source electrode is in direct contact with the semiconductor layer.

13. The display device of claim 12, wherein through a contact hole penetrating the gate insulating layer and the second dummy conductive layer, the source electrode is connected to the semiconductor layer for electrical connection.

14. The display device of claim 12, wherein the plurality of signal lines include a high-potential voltage line disposed on the substrate, and
through a contact hole penetrating the gate insulating layer and the second dummy conductive layer, the source electrode is in direct contact with the high-potential voltage line.

15. The display device of claim 1, wherein the gate insulating layer includes a first opening and a second opening, and
the gate electrode and the drain electrode are separated by the first opening, and the gate electrode and the source electrode are separated by the second opening.

16. The display device of claim 15, further comprising a passivation layer disposed on the thin film transistor, and
wherein the passivation layer fills the first and second openings.

17. The display device of claim 16, further comprising a plurality of alignment keys disposed in the non-display area on an upper surface of the substrate,
wherein the plurality of alignment keys have a same structure as the second conductive layer.

18. A display device, comprising:
a substrate;
a display area including a plurality of sub-pixels; and
a non-display area outside the display area,
wherein:
each of the plurality of sub-pixels includes a transistor disposed on the substrate;
the transistor includes a gate insulating layer disposed on the substrate, a gate electrode disposed on the gate insulating layer, and a source electrode and a drain electrode disposed on the gate insulating layer;
the gate electrode includes a first conductive layer disposed on the gate insulating layer and a second conductive layer disposed on the first conductive layer;
the first conductive layer includes a material having a lower reflectivity than the second conductive layer; and
a first dummy conductive layer is disposed between the gate insulating layer and the drain electrode and is spaced apart from the first and second conductive layers.

19. A method of manufacturing a display device including sub-pixels in a display area, wherein each of the sub-pixels includes a transistor, wherein the method comprises:
providing a substrate;
providing a semiconductor layer of the transistor on the substrate;
providing a gate insulating layer on the semiconductor layer;
providing a first conductive material on the gate insulating layer;
providing a second conductive material on the first conductive material; and
etching the first and second conductive materials, and
wherein:
etching the first and second conductive materials forms a gate electrode comprising a first conductive layer and a second conductive layer of the transistor and simultaneously forms a first dummy conductive layer that is spaced apart from the first and second conductive layers; and
the first conductive material includes a material having a lower reflectivity than the second conductive material.

20. The method of claim 19, further comprising:
providing a third conductive material on the second conductive material;
providing a conductive material on the third conductive material; and
etching the conductive material,
wherein:
etching the first and second conductive materials includes simultaneously etching the first, second and third conductive materials;
simultaneously etching the first, second and third conductive materials forms the gate electrode comprising the first conductive layer, the second conductive layer, and a third conductive layer of the transistor and simultaneously forms the first dummy conductive layer that is spaced apart from the first, second and third conductive layers; and
etching the conductive material forms a fourth conductive layer of the gate electrode, a source electrode, and a drain electrode simultaneously.
